(19) United States
(12) Patent Application Publication
(10) Pub. No.: US 2020/0033661 A1
(43) Pub. Date: Jan. 30, 2020

(54) PACKAGE STRUCTURE OF DISPLAY MODULE AND DISPLAY DEVICE

(71) Applicants: HKC Corporation Limited, Baoan Dist, Shenzhen (CN); Chongqing HKC Optoelectronics Technology Co., Ltd., Chongqing (CN)

(72) Inventor: CHUNG-KUANG CHIEN, Chongqing (CN)

(21) Appl. No.: 15/740,350

(22) PCT Filed: Jul. 26, 2017
(86) PCT No.: PCT/CN2017/094554

§ 371 Date: Dec. 28, 2017

(30) Foreign Application Priority Data
Mar. 28, 2017 (CN) 201710191461.5

(51) Int. Cl. G02F 1/1333; H05K 1/02; H01L 23/00

(52) U.S. Cl. CPC G02F 1/133305; H01L 23/562; G02F 1/133308; H05K 1/0271

(57) ABSTRACT

A package structure of a display module and a display device is provided. The package structure of the display module includes: a package substrate, a display panel positioned on the package substrate, and a stress absorbing adhesive attached to the package substrate and a protective cover plate. The package substrate, the stress absorbing adhesive and the protective cover plate seal out a space. The space is positioned between the package substrate and the protective cover plate. The display panel is positioned in the space. Wherein, the stress absorbing adhesive is configured to absorb thermal stress when the temperature is varied.

### CROSS-REFERENCE TO RELATED APPLICATION

This application claims the benefit of China Patent Application No. 201710191461.5, filed on Mar. 28, 2017, in the State Intellectual Property Office of the People's Republic of China, the disclosure of which is incorporated herein in its entirety by reference.

### BACKGROUND OF THE INVENTION

### 1. Field of the Invention

The present disclosure is related to a package structure of a display module and a display device.

### 2. Description of the Related Art

Recently, flat display devices gradually replace traditional cathode raytube (CRT) display devices along with the evolution of techniques of flat display. Flat display devices have the advantages of relatively lighter, thinner, and better power saving ability.

Flat display devices comprise liquid crystal displays (LCDs), plasma display panels (PDPs), organic light emitting diode (OLED) display devices and so on. The upper and lower surfaces of these flat display devices are attached by substrates, which are used as protective plates of a display panel.

The substrates may be warped easily when an external temperature is varied. Hence, the substrates may be separated from the display panel easily, and may damage the display panel.

### SUMMARY OF THE INVENTION

In views of above problems, the present disclosure provides a package structure of a display module and a display device to solve the problems of that a substrate is easily warped and resulted in damage of a display panel.

In the first aspect, the present disclosure provides a package structure of a display module, comprising: a package substrate, a display panel positioned on the package substrate, a protective cover plate positioned on the display panel, a stress absorbing adhesive positioned between the package substrate and the protective cover plate and positioned at the periphery edges of the display panel. Wherein, the stress absorbing adhesive is attached to the package substrate and the protective cover plate. Wherein, the stress absorbing adhesive is configured to absorb thermal stress.

In the second aspect, the present disclosure further provides a display device, which comprises the package structure of the display module as described in the first aspect.

In the third aspect, the present disclosure further provide another display device, comprising: a package substrate, a display panel positioned on the package substrate, a protective cover plate for sealing a space and connected with the package substrate. Wherein, the space is positioned between the package substrate and the protective cover plate. Wherein, the display panel is positioned in the space. Wherein, the stress absorbing adhesive is configured to absorb thermal stress.

In the embodiments of the present disclosure providing the package structure of the display module and the display device, the package structure of the display module comprises a package substrate, a display panel, a protective cover plate and a stress absorbing adhesive positioned between the package substrate and the protective cover plate, and positioned at the periphery edges of the display panel. Wherein, the package substrate and the protective cover plate are attached by the stress absorbing adhesive. The thermal stress generated by the package substrate and the protective cover plate when the external temperature is varied is absorbed by the stress absorbing adhesive, so as to prevent that the package substrate and the protective cover plate are warped or separated because of the difference between their thermal expansion coefficients. Hence, the packaging performance of the display module is improved.

### BRIEF DESCRIPTION OF THE DRAWINGS

Herein, appended drawings are referenced for describing the exemplary embodiments of the present disclosure in details. A person having ordinary skill in the art is able to understand the above features and the others.

FIG. 1 is a structural schematic view of the package structure of a display module provided by an embodiment of the present disclosure.

FIG. 2 is a schematic view shows that the stress absorbing adhesive in the position A denoted by the dotted line in FIG. 1 absorbs stress.

FIG. 3 is a schematic view shows that the stress absorbing adhesive in the position A denoted by the dotted line in FIG. 1 transmits heat.

FIG. 4 is a structural schematic view of another package structure of a display module provided by an embodiment of the present disclosure.

FIG. 5 is a structural schematic view of another package structure of a display module provided by an embodiment of the present disclosure.

FIG. 6 is a structural schematic view of a display device provided by an embodiment of the present disclosure.

### DESCRIPTION OF THE PREFERRED EMBODIMENTS

In the following paragraphs, the technical solutions of the present disclosure are explained by embodiments in combination with the appended drawings. The embodiments described here are only for explaining the present disclosure but not for limiting the present disclosure. It has to be further explained that, for ease of description, only part of structure related to the present disclosure are shown in the appended drawings but not the whole structure is shown. The following embodiments and features in the embodiments may be combined with each other at will in a condition without conflict.

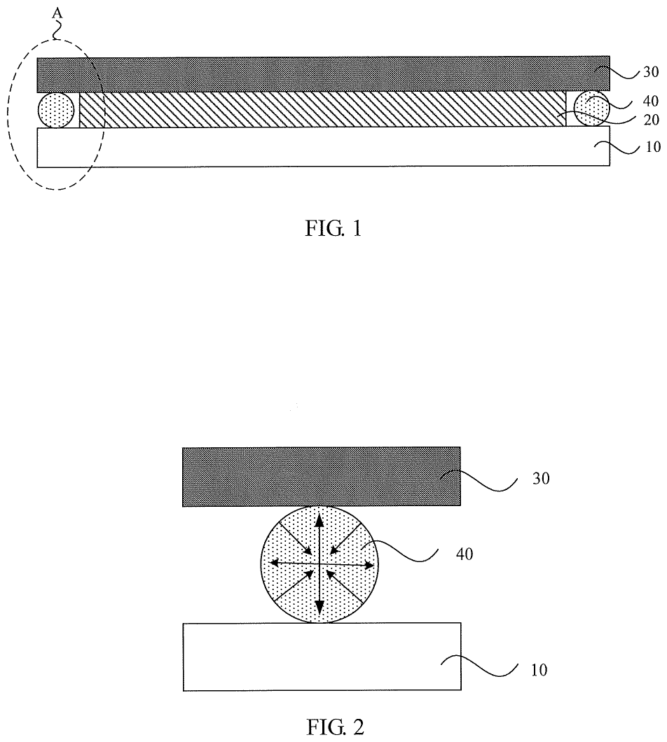

FIG. 1 is a structural schematic view of the package structure of a display module provided by the present disclosure. As shown in FIG. 1, the package structure of the display module may comprise: a package substrate 10, a display panel 20 positioned on the package substrate 10, a protective cover plate 30 positioned at a side far away from the package substrate 10 on the display panel 20, and a stress absorbing adhesive 40 positioned between the package substrate 10 and the protective cover plate 30 and positioned at the periphery edges of the display panel 20. The stress absorbing adhesive 40 is attached to the package substrate 10 and the protective cover plate 30 and absorbs the thermal stress generated by the package substrate and the protective cover plate 30 when the external temperature is varied.

Exemplary, the materials of the package substrate 10 and the protective cover plate 30 may be the same, or may be not the same. The embodiments of the present disclosure will be explained by an example of that the materials of the package substrate 10 and the protective cover plate 30 are not the same. Alternatively, the material of the package substrate 10 may be plastic. It has to be explained that the thickness of the package substrate 10 is not limited in the present disclosure, but is only needed to achieve a normal package function.

The display panel 20 is positioned on the package substrate 10. The display panel 20 in the embodiments of the present disclosure may be a liquid crystal display panel, or may be an organic light emitted display panel. The embodiments of the present disclosure will be explained by an example of that the display panel 20 is a liquid crystal display panel. Alternatively, when the display panel 20 is a liquid crystal display panel, the liquid crystal display panel may comprise an array substrate, a color film substrate and a liquid crystal layer (not shown in the figures) sandwiched between the array substrate and the color film. Alternatively, as shown in FIG. 1, the length of the display panel 20 in a horizontal direction is smaller than the length of the package substrate 10 in a horizontal direction. Further, the display panel 20 may be positioned at a central area of the package substrate 10.

The protective cover plate 30 is positioned at a side far away from the package substrate 10 on the display panel 20. The protective cover plate 30 is disposed to protect and to box the display panel 20 so as to ensure the normal display function of the display panel. Alternatively, the material of the protective cover plate 30 may be glass, such as transparent glass, so that a user may be ensured to watch the displayed image of the display panel 20 clearly. Alternatively, the display panel 20 is a touch display panel. The thickness of the protective cover plate 30 is smaller than the predetermined thickness so that a user may normally touch and use the display panel with influences.

Alternatively, as shown in FIG. 1, the length of the protective cover plate 30 in a horizontal direction may be the same as the length of the package substrate 10.

The stress absorbing adhesive 40 is positioned between the package substrate 10 and the protective cover plate 30 and is positioned at the peripheral edges of the display panel 20. As shown in FIG. 1, the stress absorbing adhesive 40 is positioned between the package substrate 10 and the protective cover plate 30, and is attached to the package substrate 10 and the protective cover plate 30.

The volumes of the package substrate 10 and the protective cover plate 30 are swelled or shrinked when the external temperature is varied. Further, the package substrate 10 and the protective cover plate 30 generate thermal stress. The stress absorbing adhesive 40 provided by the embodiments of the present disclosure may absorb the thermal stress generated by the package substrate 10 and the protective cover plate 30 when the external temperature is varied, so as to prevent that the package substrate 10 and the protective cover plate 30 are warped or separated. FIG. 2 is a schematic view that the stress absorbing adhesive in the position A denoted by the dotted line in FIG. 1 absorbs stress. When the external temperature is raised, the stress absorbing adhesive 40 may absorb the thermal stress generated by the package substrate 10 and the protective cover plate 30. Further, the stress absorbing adhesive 40 may release a part of the stress in order to ensure that the stress absorbing adhesive 40 may not deform or have a smaller deformation.

Alternatively, the stress absorbing adhesive 40 is insensitive to temperature changes. When the temperature is varied, the stress absorbing adhesive 40 has a smaller deformation or does not deform. Further, the stress absorbing adhesive 40 may resist high temperature or low temperature. The functions thereof do not change or only changes a little. Alternatively, the stress absorbing adhesive 40 comprises at least one of the following materials: an epoxy resin, polymethylmethacrylate (PMMA), a vinyl ether resin and an acrylate resin.

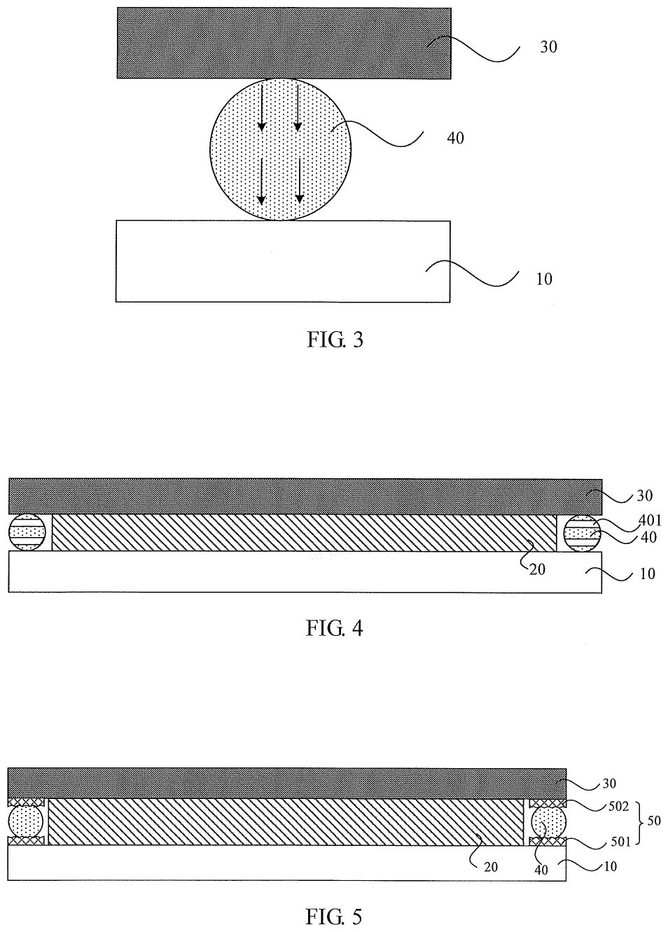

Alternatively, the stress absorbing adhesive 40 is a thermal conductive adhesive. When the external temperature of the package structure of the display module is varied, the stress absorbing adhesive 40 maintains the package substrate 10, the protective cover plate 30 and the stress absorbing adhesive in a thermal equilibrium state, so as to prevent the temperature of the package substrate 10 or the protective cover plate changes too quickly. When the materials of the package substrate 10 and the protective cover plate 30 are different, such as, the material of the package substrate 10 is plastic and the material of the protective cover plate 30 is glass, the heat capacities of the package substrate 10 and the protective cover plate 30 are different. Hence, when the external environment is varied, the temperature changes of the package substrate 10 and the protective cover plate 30 are different. In this case, the stress absorbing adhesive 40 may further transmit heat between the package substrate 10 and the protective cover plate 30, so as to maintain the package substrate 10, the protective cover plate 30 and the stress absorbing adhesive 40 in a thermal equilibrium state as shown in FIG. 3.

Alternatively, the stress absorbing adhesive 40 may be configured to absorb the mechanic stress generated by the package substrate 10 and the protective cover plate 30 when the external environment is varied, such as, the pressure stress received during a handling to transporting process, so as to ensure that the package substrate 10 and the protective cover plate 30 may not be damaged.

In summary, the package structure of the display module provided by the embodiment of the present disclosure comprises a package substrate, a display panel, a protective cover plate and a stress absorbing adhesive positioned between the package substrate and the protective cover plate and positioned at the periphery edges of the display panel. The stress absorbing adhesive is attached to the package substrate and the protective cover plate, and absorbs the thermal stress generated by the package substrate and the protective cover plate when the external temperature is varied so as to prevent that the package substrate and the protective cover plate are warped or separated because of the difference between their thermal expansion coefficients, in order to improve the packaging performance of the display module.

FIG. 4 is a structural schematic view of another package structure of a display module provided by an embodiment of the present disclosure.

As shown in FIG. 4, the package structure of a display module may comprise: a package substrate 10; a display panel 20 positioned on the package substrate 10; a protective cover plate 30 positioned at a side far away from the package substrate 10 on the display panel 20; and a stress absorbing adhesive 40 positioned between the package substrate 10 and the protective cover plate 30 and positioned at the periphery edges of the display panel 20. The stress absorbing adhesive 40 is attached to the package substrate 10 and the protective cover plate 30 and absorbs the thermal stress generated by the package substrate 10 and the protective cover plate 30 when the external temperature is varied.

A plurality of honeycomb-like holes 401 are disposed in the stress absorbing adhesive 40. The holes 401 are used for dissipating the heat generated by the display panel 20.

Exemplary, as shown in FIG. 4, a plurality of honeycomb-like holes 401 are disposed in the stress absorbing adhesive 40. The heat generated during the working process of the display panel 20 may be dissipated from the holes 401, further to prevent affecting the display quality of the display panel 20 because of the overheat of the display panel 20. Simultaneously, the service life of the display panel 20 may be increased.

In summary, a stress absorbing adhesive is disposed between the package substrate and the protective cover plate of the package structure of the display module provided by the embodiment of the present disclosure, wherein holes are disposed in the stress absorbing adhesive. The stress absorbing adhesive has holes disposed therein, and is not only able to be attached to the package substrate and the protective cover plate, but is also able to absorb the thermal stress generated by the package substrate and the protective cover plate when the external temperature is varied, so as to prevent that the package substrate and the protective cover plate are warped or separated because of the difference between their thermal expansion coefficients. Hence, the packaging performance of the display module is improved. Furthermore, the heat generated during the working process of the display panel may be dissipated from the holes disposed in the stress absorbing adhesive, further to ensure the display command of the display panel and improve the service life of the display panel.

FIG. 5 is a structural schematic view of yet another package structure of a display module provided by an embodiment of the present disclosure. As shown in FIG. 5, the package structure of the display module may comprise: a package substrate 10, a display panel 20 positioned on the package substrate 10, a protective cover plate 30 positioned at a side far away from the package substrate 10 on the display panel 20, a stress absorbing adhesive 40 positioned between the package substrate 10 and the protective cover plate 30 and positioned at the periphery edges of the display panel 20. The stress absorbing adhesive 40 is attached to the package substrate 10 and the protective cover plate 30 and absorbs the thermal stress generated by the package substrate 10 and the protective cover plate 30 when the external temperature is varied. An adhesive layer 50 is disposed at a side of the package substrate 10 and/or the protective cover plate 30, of which the side is faced toward the stress absorbing adhesive 40. The adhesive layer 50 is disposed corresponding to the stress absorbing adhesive 40.

In the present embodiment, a first adhesive layer 501 is disposed between the package substrate 10 and the stress absorbing adhesive 40. A second adhesive layer 502 is disposed between the protective cover plate 30 and the stress absorbing adhesive 40.

As shown in FIG. 5, a first adhesive layer 501 is disposed at a side of the package substrate 10, of which the side is faced toward the stress absorbing adhesive 40. A second adhesive layer 502 is disposed at a side of the protective cover plate 30, of which the side is faced toward the stress absorbing adhesive 40. By disposing the first adhesive layer 501 and the second adhesive layer 502 at the positions corresponded to the stress absorbing adhesive 40, the adhesiveness between the package substrate 10 and the stress absorbing adhesive 40 and the adhesiveness between the protective cover plate 30 and the stress absorbing adhesive 40 may be improved. The warping or separating of the package substrate 10 and the protective cover plate 30 often occurs at edge positions. The adhesive layer 50 may improve the packaging performance of the display module so as to prevent the warping or separating occurred at the package substrate 10 and/or the protective cover plate 30, or to reduce the possibility of the warping or separating occurred at the package substrate 10 and/or the protective cover plate 30. Hence, the packaging quality of the display module is improved.

Alternatively, the adhesive layer 50 is a roughened layer, which may improve the adhesiveness of between the package substrate 10, the protective cover plate 30 and the stress absorbing adhesive 40, and may further improve the packaging performance of the display module. Alternatively, a roughened layer may be formed by means of adding a roughened layer between the package substrate 10, the protective cover plate 30 and the stress absorbing adhesive 40, as well as applying a roughening treatment to positions on the package substrate 10 and the protective cover plate 30 of which the positions are corresponded to that of the stress absorbing adhesive 40. The embodiments of the present disclosure do not limit the means of forming the roughened layer, but only need to form a roughened layer between the package substrate 10, the protective cover plate 30 and the stress absorbing adhesive 40, and to ensure that the adhesiveness between the package substrate 10, the protective cover plate 30 and the stress absorbing adhesive 40 may be improved, further to improve the packaging performance of the display module.

In summary, the package structure of the display module provided by the embodiment of the present disclosure comprises a package substrate, a display panel, a protective cover plate, a stress absorbing adhesive positioned at the periphery edges of the display panel on the package substrate, and a high adhesive layer positioned at a side of the package substrate and/or the protective cover plate of which the side is faced toward the stress absorbing adhesive. The high adhesive layer is disposed corresponding to the stress absorbing adhesive. The high adhesive layer improves the adhesiveness between the stress absorbing adhesive and the package substrate as well as the protective cover plate, and further improves the packaging performance of the display module so as to prevent the warping and separating of the package substrate and/or the protective cover plate. Hence, the packaging quality of the display module is improved.

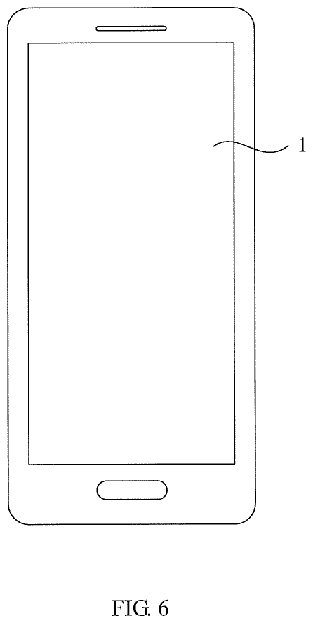

FIG. 6 is a structural schematic view of a display device provided by an embodiment of the present disclosure. The display device comprises the package structures 1 of the display module described in the above embodiments. The display device may be smart devices such as a cellphone.

It is to be noticed, the aforementioned contents are merely embodiments and technical principles used therein of the present disclosure. A person skilled in the related art is able to know that the present disclosure is not limited to specific embodiments described herein. A person skilled in the related art is able to know that any obvious modifications, re-alterations and replacements are able to be implemented but not depart from the scope of the appended claims. Hence, although detailed description of the present disclosure are explained by above embodiments, the present disclosure are not only limited to the above embodiments. Any equivalent embodiments which do not depart from the concept of the present application are intended to be comprised within the scope of the present disclosure. Whereas, the scope of the present disclosure is determined by the scope of the appended claims.

What is claimed is:

1. A package structure of a display module, comprising:
a package substrate;
a display panel positioned on the package substrate;
a protective cover plate positioned on the display panel; and
a stress absorbing adhesive positioned between the package substrate and the protective cover plate, and positioned at the periphery edges of the display panel;
wherein the stress absorbing adhesive is attached to the package substrate and the protective cover plate; and
wherein the stress absorbing adhesive is configured to absorb thermal stress.

2. The package structure of the display module as claimed in claim 1, wherein the stress absorbing adhesive maintains the package substrate, the protective cover plate and the stress absorbing adhesive in a thermal equilibrium state when an external temperature of the package structure of the display module is varied.

3. The package structure of the display module as claimed in claim 1, wherein the stress absorbing adhesive comprises at least one of the following materials: an epoxy resin, polymethylmethacrylate (PMMA), a vinyl ether resin and an acrylate resin.

4. The package structure of the display module as claimed in claim 1, wherein the stress absorbing adhesive further absorbs a mechanic stress of the package substrate and the protective cover plate when the external environment is varied.

5. The package structure of the display module as claimed in claim 1, wherein a hole for heat dissipation is disposed in the stress absorbing adhesive.

6. The package structure of the display module as claimed in claim 1, wherein
a first adhesive layer is disposed between the package substrate and the stress absorbing adhesive; and
a second adhesive layer is disposed between the protective cover plate and the stress absorbing adhesive.

7. The package structure of the display module as claimed in claim 6, wherein both of the first adhesive layer and the second adhesive layer are roughened layers.

8. The package structure of the display module as claimed in claim 1, wherein
the material of the package substrate is plastic; and
the material of the protective cover plate is glass.

9. The package structure of the display module as claimed in claim 1, wherein the display panel is a liquid crystal display panel.

10. A display device, comprising:
a package structure of a display module;
wherein the package structure of the display module comprises:
a package substrate;
a display panel positioned on the package substrate;
a protective cover plate positioned on the display panel;
a stress absorbing adhesive positioned between the package substrate and the protective cover plate, and positioned at the periphery edges of the display panel,
wherein the stress absorbing adhesive is attached to the package substrate and the protective cover plate; and
wherein the stress absorbing adhesive is configured to absorb thermal stress.

11. The display device as in claimed claim 10, wherein the stress absorbing adhesive maintains the package substrate, the protective cover plate and the stress absorbing adhesive in a thermal equilibrium state when an external temperature of the package structure of the display module is varied.

12. The display device as in claimed claim 10, wherein the stress absorbing adhesive comprises at least one of the following materials: an epoxy resin, polymethylmethacrylate (PMMA), a vinyl ether resin and an acrylate resin.

13. The display device as claimed in claim 10, wherein a hole for heat dissipation is disposed in the stress absorbing adhesive.

14. The display device as claimed in claim 10, wherein
a first adhesive layer is disposed between the package substrate and the stress absorbing adhesive; and
a second adhesive layer is disposed between the protective cover plate and the stress absorbing adhesive.

15. The display device as claimed in claim 10, wherein
the material of the package substrate is plastic; and
the material of the protective cover plate is glass.

16. A package structure of a display module, comprising:
a package substrate;
a display panel positioned on the package substrate;
a protective cover plate for sealing a space, connected with the package substrate by a stress absorbing adhesive, wherein
the space is positioned between the package substrate and the protective cover plate; and
the display panel is positioned in the space;
wherein the stress absorbing adhesive is configured to absorb thermal stress when temperature is varied.

17. The package structure of the display module as claimed in claim 16, wherein the stress absorbing adhesive comprises at least one of the following materials: an epoxy resin, polymethylmethacrylate (PMMA), a vinyl ether resin and an acrylate resin.

18. The package structure of the display module as claimed in claim 16, wherein
a first adhesive layer is disposed between the package substrate and the stress absorbing adhesive; and
a second adhesive layer is disposed between the protective cover plate and the stress absorbing adhesive.

19. The package structure of the display module as claimed in claim 16, wherein a hole for heat dissipation is disposed in the stress absorbing adhesive.

20. The package structure of the display module as claimed in claim 16, wherein the stress absorbing adhesive maintains the package substrate, the protective cover plate and the stress absorbing adhesive in a thermal equilibrium state when an external temperature of the package structure of the display module is varied.
